(19) United States
(12) Patent Application Publication
(10) Pub. No.: US 2014/0102523 A1
(43) Pub. Date: Apr. 17, 2014

(54) HYBRID SOLAR CELL CONTACT

(71) Applicants: Stuart Ross Wenham, Cronulla (AU); Ly Mai, Sefton (AU)

(72) Inventors: Stuart Ross Wenham, Cronulla (AU); Ly Mai, Sefton (AU)

(73) Assignee: NEWSOUTH INNOVATIONS PTY LIMITED, UNSW Sydney, NSW (AU)

(21) Appl. No.: 14/009,669

(22) PCT Filed: Apr. 10, 2012
(86) PCT No.: PCT/AU12/00367

§ 371 Date: Nov. 14, 2013

(30) Foreign Application Priority Data
Apr. 7, 2011 (AU) 2011901293

(51) Int. Cl. H01L 31/0352; H01L 31/0224

(52) U.S. Cl. CPC H01L 31/03529; H01L 31/022433
USPC 136/255

(57) ABSTRACT

A solar cell and a method of forming a solar cell comprising: a semiconductor body having a p-n junction located between a front (light receiving) semiconductor region and a back (non-light receiving) semiconductor region; a dielectric layer extending over a front surface of the front semiconductor region; one or more elongate semiconductor fingers formed on the front surface of the front semiconductor region, the semiconductor fingers being exposed through the dielectric layer, more heavily doped than the remainder of the front semiconductor region and of the same dopant polarity; one or more elongate plated contacts formed to self align with and at least partially cover the semiconductor fingers; one or more metal collection fingers extending over the dielectric layer, generally transversely to the plated contacts.

### INTRODUCTION

The present invention relates to solar cells and in particular to a new method of making electrical connection to such cells.

### BACKGROUND

Screen-printed solar cells continue to dominate commercial manufacturing with well over 50% market share. The device of FIG. 1 (not to scale) shows, by way of example, a silicon solar cell 11 with screen printed contacts and includes a p-type wafer 12 with isotropic texturing 13 of the front surface (throughout this specification the term “front surface” refers to the light receiving surface and the terms “rear surface” or “back surface” refer to the non-light receiving surface), a front surface diffusion of n-type dopant 14, to form p-n junction 19, a screen-printed rear (non-light receiving) surface contact, a back surface field 16, and screen-printed front surface contacts 17. The fundamental limitations of the conventional screen-printed solar cell 11 as shown in the schematic of FIG. 1, that have limited its performance for the last 30 years are well understood.

New approaches for redesigning the emitter 14 and front metal contact 17 have been devised, developed and analysed such as the incorporation of selective emitter contacting schemes. However the most fundamental limitation results from the inability to reliably screen-print metal lines of width less than 100 microns in large scale commercial production. Lines of such large width, when applied to the light receiving surface of the solar cell, need to be spaced at least 2 mm apart to prevent excessive metal shading losses. This spacing is too great to allow emitters with sheet resistivity above 100 ohms per square to be used due to excessive lateral resistance losses in the emitter. However emitters with sheet resistivity below 100 ohms per square generally suffer from poor response to short wavelength light as the collection probabilities for charge generated within the emitter fall to well below unity.

In general an emitter sheet resistivity above 100 ohms per square will allow near perfect response to short wavelengths of light provided the surface of the solar cell is well passivated. In the range of 80-100 ohms per square, near perfect response to short wavelengths of light can still be achieved, but only if careful attention is paid to the doping profile of the emitter and provided the surface is well passivated. Below 80 ohms per square, some loss in short wavelength response is inevitable.

In addition the large metal/silicon interface area, that results from the use of conventional screen painting of contacts, limits open circuit voltages of cells to values well below those that would otherwise be achievable and those that have been demonstrated by other metallization techniques that achieve much lower metal/silicon interface areas, such as those based on plated contacts or those formed through the use of photolithography in conjunction with evaporated, sputtered or plated metal contacts.

One innovative approach to trying to accommodate a front surface emitter sheet resistivity of at least 90 ohms per square and preferably 100 ohms per square while still using screen-printed metal contacts is the concept of the semiconductor finger. This concept was devised in recognition of the fact that metal fingers need to be spaced no more than 1 mm apart, when using a front surface emitter sheet resistivity of at least 100 ohms per square, to avoid excessive sheet resistivity losses. Due to the large width of screen printed metal lines of 100 microns or more, such a close spacing is not possible without shading well over 10% of the cell surface. The concept of semiconductor fingers was therefore introduced as shown in FIG. 2. These semiconductor fingers can be formed by patterning the dielectric layer and then heavily doping the exposed silicon to improve its conductivity in localised areas to act as the semiconductor fingers. The strength of this approach is that the use of such semiconductor fingers facilitates the use of a lightly doped emitter with sheet resistivity above 100 ohms per square because they can be made quite narrow and can be spaced less than 1 mm apart. The charge collected by the junction can therefore flow with minimal resistive losses to the nearby semiconductor fingers which then conduct the current to the screen-printed metal lines that run perpendicularly to the semiconductor fingers. However the conductivity of such semiconductor fingers is quite limited with sheet resistivities of below 2 ohms per square being difficult to achieve without thermal treatments that will cause damage to the wafer. Such fingers are therefore limited in their length if they are not to incur excessive resistive losses. This length limitation in turn typically limits the spacing between the screen-printed contacts to values not much greater than used in conventional screen-printed devices.

Referring to FIG. 2 a section of a solar cell is illustrated (not to scale) showing screen-printed fingers 17 running perpendicular to the heavily diffused semiconductor fingers 22. The lightly diffused emitter 14 at the front surface collects the generated charge and conducts it to the nearby semiconductor fingers 22 spaced typically 0.8 mm apart which then conduct it to the screen-printed metal lines 17.

The main problems for this technology are that firstly, the conductivity of the semiconductor fingers 22 cannot be made high enough to be practical in a way that allows the screen-printed lines 17 to be spaced significantly further apart to reduce metal shading losses; secondly, the screen-printed metal lines 17 do not make good electrical contact to the lightly doped emitter 14 and the interface area between the semiconductor fingers 22 and the screen-printed metal 17 is not high enough to reliably make good electrical contact in large scale production; and thirdly, the metal/silicon interface area is not reduced unless a dielectric layer is used underneath the metal which will in turn cause a detrimental effect to the electrical contact between the metal and silicon. For example variability in this contact resistance between the screen-printed metal and silicon is a weakness in the design causing efficiencies in pilot production of the technology to vary from 16.5% to 18.4%, with the average being well below 18%.

However the processing sequence for this technology is easily retrofitted onto a standard screen-print line and is as follows:
1. surface texturing of wafer 12
2. diffusion of emitter 14 (100 ohms per square)
3. rear surface etch plus edge isolation
4. deposition of SiNx anti-reflection coating (ARC) 18 by PECVD (front surface)
5. form Semiconductor fingers 22 by laser doping
6. screen print the rear metal 15 plus front metal 17 contacts
7. fire the metal contacts at 750-850° C.
   Only step 5 deviates from standard homogeneous emitter screen-printed solar cell fabrication, with the overall fabrication appearing to be simpler and shorter than those sequences proposed to introduce selective emitter designs in screen-printed solar cells.

FIG. 3 shows the spectral response of the semiconductor finger cell of FIG. 2.

This concept of semiconductor fingers does not appear to have ever been used in commercial solar cells, even though it appears to have considerable appeal due to its promise to facilitate good conductivity within the emitter, without many of the normal trade-off found in screen printed cells. The low yields experienced in pilot production and failure to achieve the required level of finger conductivity are likely contributors to absence of commercial use.

### SUMMARY

A first aspect of the invention provides a solar cell comprising:

a semiconductor body having a p-n junction located between a front (light receiving) semiconductor region and a back (non-light receiving) semiconductor region;

a dielectric layer extending over a front surface of the front semiconductor region;

one or more elongate semiconductor fingers formed on the front surface of the front semiconductor region, the semiconductor fingers being exposed through the dielectric layer, more heavily doped than the remainder of the front semiconductor region and of the same dopant polarity;

one or more elongate plated contacts formed to self align with and at least partially cover the semiconductor fingers;

one or more metal collection fingers extending over the dielectric layer, generally transversely to the plated contacts,

A second aspect of the invention provides a method of forming a Solar cell comprising:

in a semiconductor body having a p-n junction located between a front (light receiving) semiconductor region and a back (non-light receiving) semiconductor region and a dielectric layer on a front surface of the front semiconductor region, forming openings in the dielectric layer and doping the front surface of the front semiconductor region through the openings to form one or more elongate semiconductor fingers on a surface of the front semiconductor region, the semiconductor fingers being more heavily doped than the remainder of the front semiconductor region and of the same polarity;

forming one or more self aligning elongate plated contacts at least partially covering the semiconductor fingers;

forming one or more metal collection fingers extending over the dielectric layer generally transversely to the plated contacts.

The one or more metal collection fingers extending generally transversely to the plated contacts are spaced apart by distances of up to 1-3 cm and are preferably spaced at a minimum spacing of 3-6 mm.

The one or more elongate semiconductor fingers may be formed on the surface of the front semiconductor region before or after the formation of the one or more metal collection fingers. Further the formation of the one or more self aligning elongate plated contacts may occur before or after the formation of the one or more metal collection fingers.

The one or more metal collection fingers extending generally transversely to the plated contacts may be e formed by depositing lines of metal paste and firing the metal paste to form the metal collection fingers, or they may be formed by depositing lines of seeding material over the dielectric layer and plating over the seeding material.

Embodiments of the invention may also incorporate one or more busbars running generally transversely to the metal collection fingers. The busbar or busbars may be formed of a fired metal paste by forming lines of metal paste and firing the metal paste. The lines of paste may be formed by screen printing or other deposition techniques such as spray deposition or inkjet techniques or similar. Alternatively the busbars may be formed by depositing lines of seeding material over the dielectric layer and plating over the seeding material.

In embodiments of the invention, the metal collection fingers may be tapered. When busbars are used the metal Collection fingers may be tapered such that they are wider where they meet the or each busbar and become narrower as they extend from the busbar.

The fired metal paste collection fingers crossing the plated contacts will typically be in the range of 40-60 microns high, but may be 10-80 microns or 10-20 microns or 20-30 microns or 30-40 microns or 40-50 microns or 50-60 microns or 60-70 microns or 70-80 microns. These fingers will typically be 450-550 microns wide (notionally 500 microns wide) at one wider end and 75-125 microns wide (notionally 100 microns wide) at the other narrower end. However, the wider end could be anywhere in the range 150-1000 microns or 150-200 microns or 200-300 microns or 300-500 microns or 400-500 microns or 500-600 microns or 600-700 microns or 700-800 microns or 800-900 microns or 900-1000 microns while the narrower end is preferably as narrow as can be reliably printed and typically 50-125 microns and preferably 75-100 microns wide. The taper is preferably constant but need not be. The busbars if used will have a cross sectional area at least as large as a cross sectional area of the collection fingers at a point where the collection fingers meet the busbars.

Methods of the invention may require the firing step to be completed before the plating step.

If the plating is applied after the metal paste is fired, the semiconductor fingers may be formed by opening an overlying dielectric layer with a Q-switched laser. The semiconductor fingers are preferably simultaneously opened and doped to a higher doping level than the remainder of the emitter and may be in the range of 1-2 microns deep but can be deeper.

The plating height will preferably be in a range of 0.5-3 microns but can be or (notionally 2 microns but alternatively in the range of 0.1-5.0 microns or 0.1-10 or 0.1-9.0 or 0.1-8.0 or 0.1-7.0 or 0.1-6.0 or 0.1-5.0 or 0.1-4.0 or 0.1-3.0 or 0.1-2.0 or 0.1-1.0 or 0.1-0.5 microns or 0.5-10 or 0.5-9.0 or 0.5-8.0 or 0.5-7.0 or 0.5-6.0 or 0.5-5.0 or 0.5-4.0 or 0.5-3.0 or 0.5-2.0 or 0.5-1.0 microns or 1.0-10 or 1.0-9.0 or 1.0-8.0 or 1.0-7.0 or 1.0-6.0 or 1.0-5.0 or 1.0-4.0 or 1.0-3.0 or 1.0-2.0 microns or 2.0-10 or 2.0-9.0 or 2.0-8.0 or 2.0-7.0 or 2.0-6.0 or 2.0-5.0 or 2.0-4.0 or 2.0-3.0 microns or 3.0-10 or 3.0-9.0 or 3.0-8.0 or 3.0-7.0 or 3.0-6.0 or 3.0-5.0 or 3.0-4.0 microns or 4.0-10 or 4.0-9.0 or 4.0-8.0 or 4.0-7.0 or 4.0-6.0 or 4.0-5.0 microns or 5.0-10 or 5.0-9.0 or 5.0-8.0 or 5.0-7.0 or 5.0-6.0 microns or 6.0-10 or 6.0-9.0 or 6.0-8.0 or 6.0-7.0 microns or 7.0-10 or 7.0-9.0 or 7.0-8.0 microns or 8.0-10.0 or 8.0-9.0 microns or 9.0-10.0 micron)

The plated contacts are preferably self aligning with the semiconductor fingers and may typically have widths in the range of 10 to 30 microns but may be in the range of 5 to 50 or 5 to 40 or 5 to 30 or 5 to 20 or 5 to 10 microns or 10 to 50 or 10 to 40 or 10 to 30 or 10 to 20 microns or 20 to 50 or 20 to 40 or 20 to 30 microns or 30 to 50 or 30 to 40 microns or 40 to 50 microns.

Embodiments of the invention may include forming the semiconductor fingers as deep junctions using a continuous wave laser (or a high frequency pulsed laser operating as a pseudo continuous wave laser, e.g. a laser operating at a pulse repetition rate of greater than 500 khz and preferably greater than 1 Mhz, optionally in the range of 500 khz to 1 Mhz or 1 Mhz-5 Mhz or 5 Mhz-10 Mhz or 10 Mhz-20 Mhz or 20 Mhz-30 Mhz or 30 Mhz-40 Mhz or 40 Mhz-50 Mhz or 50 Mhz-60 Mhz or 60 Mhz-80 Mhz or 80 Mhz-100 Mhz) to melt the silicon to a depth of greater than 1 micron, preferably greater than 5 microns and optionally greater than 10 microns during the formation of the semiconductor fingers, to extend the distance between the plated metal contacts and the p-n junction during the firing step (if the plating is applied before the metal paste is fired).

Embodiments of the invention may make use of rear surface junctions where the junction is formed adjacent the rear (non light receiving) surface of the semiconductor body (i.e. closer to the rear surface than the front surface) to extend the distance between the plated metal contacts and the p-n junction during the firing step to depths greater than 10 microns. However even when rear junctions are used it is also preferable to use a continuous wave laser (or a high frequency pulsed laser operating as a pseudo continuous wave laser as described above) to melt the silicon to a depth of greater than 1 micron, preferably greater than 5 microns and optionally greater than 10 microns, during the formation of the semiconductor fingers,

Embodiments of the invention may also include use of illumination of the silicon while the plating step is performed to prevent oxidation of exposed silicon surfaces. The use of illumination may be employed during other immersion steps such as washing to further avoid oxidation.

Importantly, by using a screen-printed paste that does not penetrate through the dielectric layer during firing, contact between the screen-printed metal (typically silver) and the lightly doped silicon is avoided. Generally, metal screen printing pastes have special additives to allow them to eat through dielectric layers such as silicon nitride or silicon dioxide etc. Without these additives, the pastes can't penetrate through the dielectric layers used for passivation and antireflection on modern silicon solar cells. By refraining from using these additives the fired metal paste can be prevented from penetrating the dielectric.

### BRIEF DESCRIPTION OF THE DRAWINGS

Embodiments of the invention will now be described by way of example with reference to the accompanying drawings in which:

FIG. 1 diagrammatically illustrates a section of a standard screen-printed solar cell in perspective;

FIG. 2 diagrammatically illustrates a section of a solar cell in perspective with screen-printed fingers running perpendicular to the heavily diffused semiconductor fingers.

FIG. 3 graphically illustrates the, spectral response of the semiconductor finger cell of FIG. 2:

FIG. 4 diagrammatically illustrates a section of a plated contact solar cell in perspective;

FIG. 5 diagrammatically illustrates a section of a screen-printed contact solar cell in perspective;

FIG. 6 diagrammatically illustrates a plan (front) view of a hybrid screen-printed and plated solar cell showing the three levels of metallisation;

FIG. 7 diagrammatically illustrates a section of the hybrid screen-printed and plated solar cell of FIG. 6 in perspective showing the three levels of metallisation;

FIG. 8 diagrammatically illustrates a section of a hybrid screen-printed and plated solar cell in perspective showing the two levels of metallisation and a wire busbar;

FIG. 9 diagrammatically illustrates use of a laser to simultaneously pattern the dielectric and melt the silicon surface, leaving the silicon surface exposed;

FIG. 10 diagrammatically illustrates a solar cell in a plating bath under illumination;

FIG. 11 diagrammatically illustrates use of a continuous wave laser to simultaneously pattern the dielectric and melt the silicon surface, forming a deep heavily doped line leaving the silicon surface exposed;

FIG. 12 diagrammatically illustrates a section of a hybrid screen-printed and plated solar cell showing the three levels of metallisation and a deep junction of the semiconductor finger under the plated metallisation; and

FIG. 13 diagrammatically illustrates a section of a hybrid screen-printed and plated solar cell showing the three levels of metallisation and a rear surface junction.

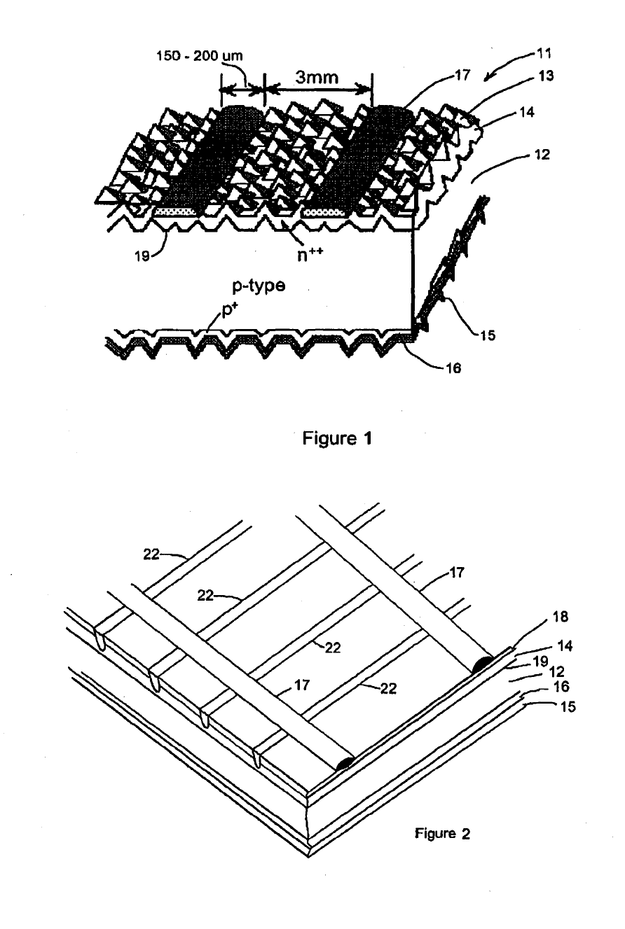

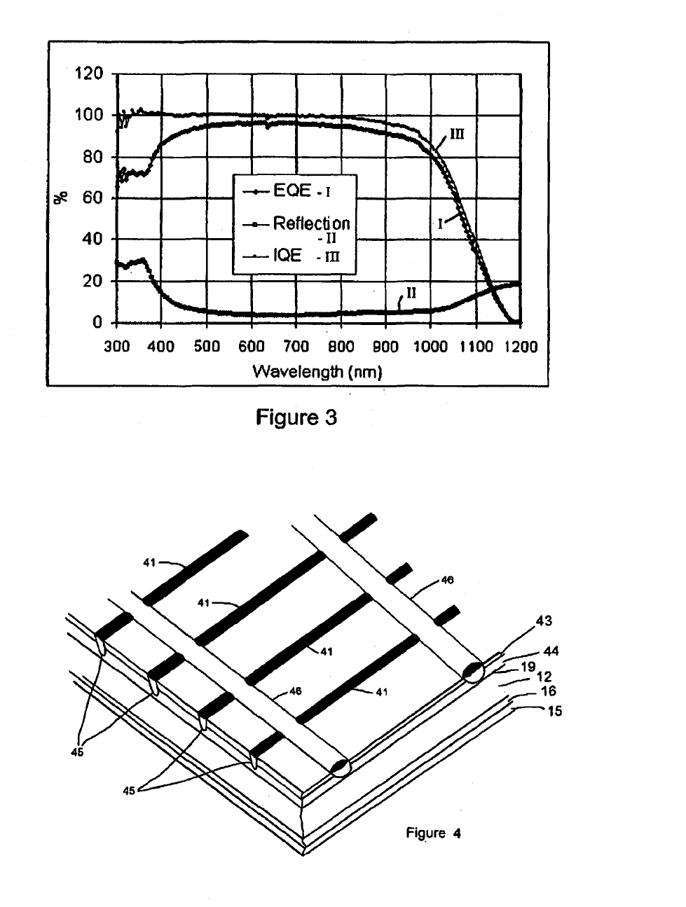

### DETAILED DESCRIPTION

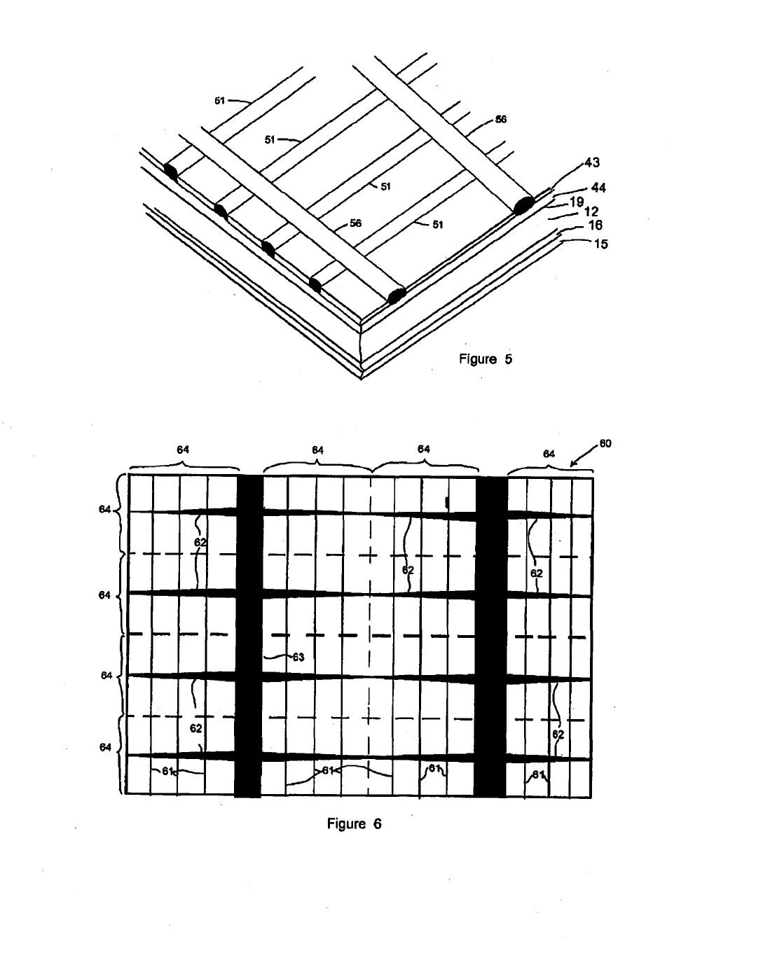

Plated contacts provide an alternative approach for overcoming the limitations of screen-printed contacts described above. This is because it is relatively simple to achieve narrow metal lines that overcome the high shading losses associated with screen-printed contacts when they are spaced only about 1 mm apart. FIG. 4 diagrammatically illustrates (not to scale) a portion of a plated solar cell. FIG. 5 diagrammatically illustrates (not to scale) a screen-printed solar cell. In FIG. 4, the plated metal lines 41, despite being spaced less than 1 mm apart, shade significantly less of the solar cell surface than the screen printed lines 51 of FIG. 5. This is due to the plated lines 41 being less than 30 microns wide compared to the 100 microns wide screen printed lines 51. Such narrow lines are relatively easily achieved by patterning 45 the dielectric layer 43 (normally silicon nitride deposited by PECVD) such as by laser patterning, inkjet patterning, or photolithography, to expose lines of silicon 45 to be prepared on the front surface of the silicon layer 44 to be plated. The lines 45 are prepared by doping during or after their formation such as by forming the lines 45 with a laser in the presence of a dopant source, or by opening lines in the dielectric 43 and then diffusing dopant into the surface, for example. This will result in the doped lines 45 then being more heavily doped than the front silicon layer 44.

In the screen printed cell of FIG. 5 the patterning of the dielectric and the doping of the front surface under the contact are not required as the metal paste of the screen printed contact 51 and busbar 56 penetrates the dielectric layer 43 during firing to contact the front semiconductor layer 44. However because the screen printed contacts cannot be reliably formed at less than about 100 micron widths (and certainly not less than 50 micron widths) in commercial production, significant shading occurs with screen printed contacts.

Despite the higher performance able to be achieved with plated contacts, only about 1% of present solar cell manufacturers use such plated contacts. This is because: firstly, the adhesion of plated contacts tends to be significantly worse than for screen-printed solar cells; secondly, in larger cell which are becoming more prevalent, the plating process is very slow because the metal needs to be plated to a height of at least 8 microns and preferably more than 10 microns, to allow the current to be carried the distances involved to reach the busbars 46 without incurring excessive resistive losses; thirdly, there is a tendency during the plating process for ghost plating to occur to unwanted areas through pinholes in the silicon nitride; fourthly, the thermal expansion mismatch between the metal and the silicon means that for metal layers that are so high, the stress within the metal often leads to it peeling away from the silicon surface even without the application of any mechanical stress; and fifthly, conventional soldering techniques for cell interconnection that work with screen-printed contacts cannot be used with such plated contacts.

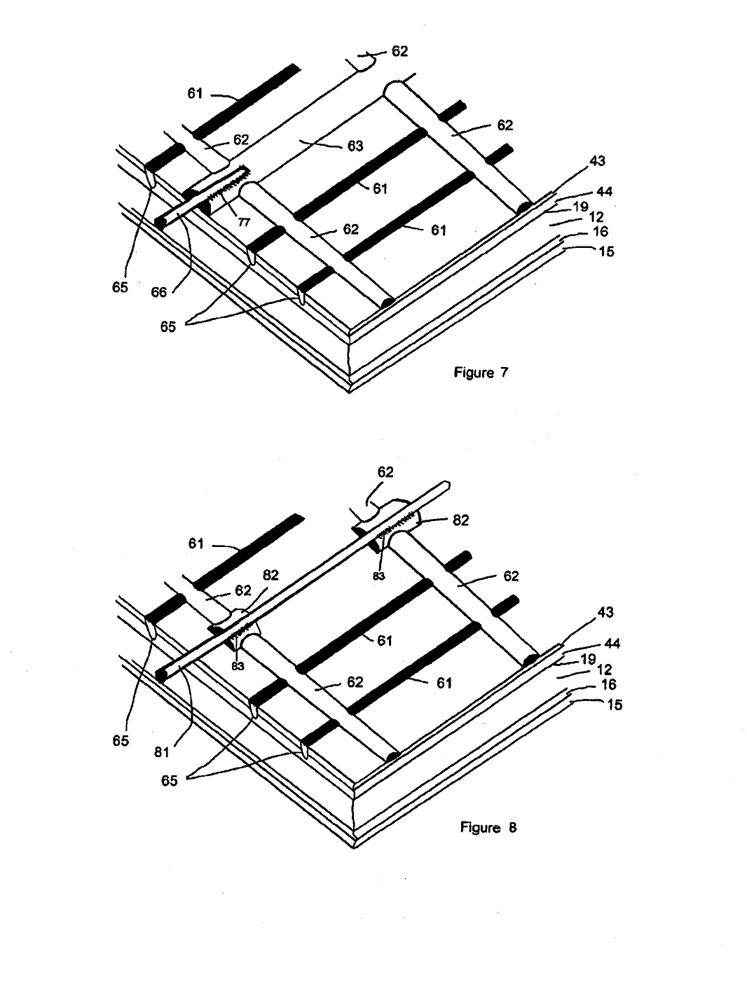

It is now proposed to use a hybrid technology that combines plating and screen-printing techniques in a novel manner, while improving cell performance over that of screen-printed contacts alone. In this approach, for which a schematic is illustrated in FIG. 6, and a diagrammatic partial perspective view is illustrated in FIG. 7 (neither to scale), elongated plated contacts 61 are used in a first level of metallization, which can have quite small feature sizes such as metal lines within the range of 5 to 50 microns, making them well suited for being closely spaced and therefore able to efficiently collect the generated current when connected to the front semiconductor layer 44 via the doped channels 65 (see FIG. 7).

As a second level of metallization, screen-printed contacts 62 are excellent for carrying moderate currents moderate distances, but are unable to achieve the fine feature sizes below 50 microns achievable by plated contacts 61 and needed to allow the close spacing required so as to efficiently collect the current directly from the semiconductor material without resorting to undesirably low surface resistivity or causing undue shading. When such screen printed contacts 62 are used to collect current for a plurality of plated contacts 61 they can be spaced more widely than when used as a first level contact, without excessive detrimental effect.

Screen-printed busbars 63 may be provided as a final stage of current conduction from the cell and will run close to the full width of the cell as shown in FIG. 6. These busbars 63 optionally form a third level of metallization and may be used to collect the large amounts of current generated by the cell and allow the current to be conducted from the solar cell via interconnect wires 66 soldered 77 to the busbars 63 or by some other contacting approach, usually to an adjacent solar cell or output terminals. Alternatively the screen-printed busbars 63 can be omitted and replaced with wire busbars 81 (see FIG. 8) or other collection means which may for example be soldered 83 to tabs 82 on the first mentioned screen-printed contacts 62.

The multiple levels of metallisation are not important for small area cells, but the trend in the industry is for cell sizes to continually increase making a metallisation scheme combining fine plated contacts 61 and course screen printed contacts 62 & 63 of significant importance to more efficiently conduct the corresponding large currents that have to travel long distances, across the solar cell. The large area solar cell can be thought of as comprising many smaller solar cells 64 (see FIG. 6) in parallel, each of which are basically plated solar cells of high efficiency, but only needing small (typically 0.1-5 microns and notionally 2 microns) thickness of plated metal 61 due to the small size of the cell 64 and the corresponding short lengths for the plated metal lines. Each such small plated solar cell 64 has at least one screen-printed line passing through it as shown in FIG. 6, that collects the current generated by that cell 64 and carries it to the busbar 63 or interconnect wire 81. This solves the problem of having to plate the metal lines to at least 8 microns in height to carry the current longer distances in a two-level metallisation scheme for a plated solar cell 40. It also avoids incurring excessive shading losses or poor short wavelength response that would be caused by having wider screen-printed metal lines too close together or a low resistivity in the front silicon layer in the case of a two-level screen-printed solar cell 50.

The screen-printed contacts 62, 63 are ideal for the role of carrying the current relatively long distances from each small cell 64 where the large width and ability to be printed at heights (i.e. thicknesses) approaching 50 microns become significant strengths of the screen printed conductors, rather than weaknesses.

Similarly, the ability to produce very narrow metal lines through plating that have good adhesion strength because they are only plated to a height of 0.1-5 microns, makes them ideal for use in the small cells 64 as the first metallisation level where their close spacing and low shading loss make much higher efficiencies achievable.

The screen-printed busbars 63, combined with soldered or glued interconnect wires are very effective for a third level of metallisation, for carrying the largest currents the longest distances. In combination, large area cells of high efficiency can be fabricated with metal contacts 61, 62, 63 that have excellent adhesion strength and are solderable for the interconnects. In the case of the cell design of FIGS. 6 & 7, there are effectively 16 small area cells 64, each of approximately 15 cm² and each connected by a single screen printed tapered line 62 that connects each of the small cells 64 to the closer of the two busbars 63.

In general, the concept of a hybrid structure 60 combining screen-printed contacts 62, 63 and plated contacts 61 in the same metallization scheme would be considered an impossibility for several masons.

Firstly, if the plated contacts 61 are formed first, they would be expected to be destroyed by the high firing temperatures for the screen-printed contacts 62, 63 that normally exceed 800° C. (but may be in the range of 750°-850° C.), while simultaneously leading to sonic of the plated metal being driven so deeply into the silicon 44 that it would cause significant damage, particularly to the junction 19 which normally resides typically a micron or less from the surface.

Secondly, if the plated contacts are formed after the screen printed contacts, it is difficult to simultaneously plate different surfaces of drastically different electrical conductivity, with the more conductive surface being preferentially plated over the less conductive one. This principle has in fact been used to advantage by manufacturers of screen-printed solar cell who have elected to improve the conductivity of their screen-printed lines by plating them, relying on the fact that exposed silicon through pinholes in silicon nitride passivation or ARC layers will not ghost plate due to the big difference in conductivities of such exposed surface regions compared to the screen-printed metal. In the hybrid approach however, the deliberate use of very heavy doping of the surface of the regions to be plated to increase the conductivity has been shown to be effective. Laser melting of such regions is particularly effective since the segregation coefficients of most metals and dopants in molten silicon are sufficiently small that these collect at the surface where the last part of the silicon freezes, in turn helping the subsequent plating process.

Thirdly, forming the plated contacts after forming the screen-printed contacts makes it very difficult to plate regions close to the screen-printed silver because the electrochemical potential of the silver causes it to oxidize any other materials it is in contact with. Oxidation of the exposed silicon near the screen-printed metal prevents this region from being plated and therefore prevents the plated lines from joining the screen-printed lines.

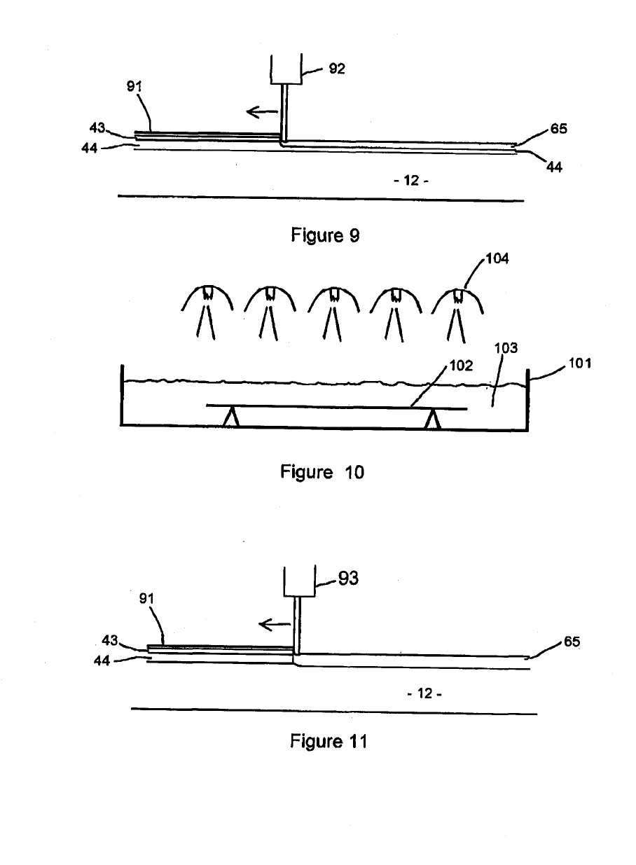

In a preferred implementation of the hybrid technology, the screen-printed silver paste is first printed onto the front surface dielectric layer 44. Following firing of the silver, a brief HF dip is used to remove any surface oxides, followed by a rinse while the wafer surface is illuminated to prevent oxidation of the exposed silicon. The front surface dielectric layer 44 is then patterned so as to intersect the screen printed silver past by one of several approaches Including through the use of inkjet technology, lasers or photolithography. This defines the paths of the plated lines which will be formed. After patterning of the dielectric layer, the silicon surface is treated such as with a laser or a thermal diffusion process to enhance its plateability. Referring to FIG. 9, in its simplest form, a laser is used to simultaneously pattern the dielectric and melt the silicon, preferably in the presence of a dopant source 91 to enhance the plateability of the silicon surface by doping. This is followed by the plating of 0.1-10.0 microns (notionally 2 microns) of silver (or Ni/Ag or Ni/Cu/Ag) to the screen-printed metal and simultaneously to the exposed regions of silicon. An optional sintering of the metal can be used depending on the metal type used and the adhesion strength required.

Alternatively, the screen-printed silver paste may be printed onto the surface after the patterning and doping steps, and optionally after the plating step, so as to intersect the patterned regions of the dielectric. Again, following firing of the silver, a brief HF dip is used to remove any surface oxides, followed by a rinse while the wafer surface is illuminated to prevent oxidation of the exposed silicon. If the screen-printing step is performed after the plating step, the optional sintering of the plated metal can be dispensed with.

Plating is preferably achieved by first preparing the areas to be plated in a manner similar to the creation of the prepared semiconductor lines 45 in the FIG. 4 example, by patterning 42 the dielectric layer 43 (normally silicon nitride deposited by PECVD) such as by laser patterning, inkjet patterning, or photolithography, to expose lines of prepared silicon 45 in the front surface of the silicon layer 44 to be plated. The prepared lines 45 are doped during or after their formation such as by forming the lines 45 with a laser 92 in FIG. 9 in the presence of a dopant source 91 such as phosphoric acid. Alternatively, lines in the dielectric 43 may be opened by inkjet patterning, or photolithography and a dopant then diffused into the surface, for example, in a conventional manner. Either way, this will result in the doped lines 45 then being more heavily doped than the front silicon layer 44. The plating step is then performed in a conventional manner except for the plating depth.

If the plating step is performed after the screen printed contacts are formed, the oxidation of the silicon may be controlled by shining a light onto the wafer surface whenever the wafer is placed into a solution where both the exposed n-type region to be plated and the exposed screen-printed metal are to be immersed (including being rinsed in water). An illuminated bath 101 suitable for performing the plating and washing steps is schematically illustrated in FIG. 10 in which the substrate 102 is immersed in the solution (plating, rinsing etc) 103 under illumination 104. Oxidation of the n-type silicon surface will tend to happen when the silver in contact with it takes a disproportionately large share of the free electrons, with the subsequent shortage of free electrons in the n-type material contributing to its oxidation. The light incident on the wafer, provided it is at least 1 mW/cm² in intensity, will generate sufficient free electrons within the n-type exposed surface to protect it from the oxidation effect of the silver and therefore minimize its oxidation. For example, during a plating process, electrons collected in the n-type surface region to be plated, leave the silicon surface to combine with a positively charged metal ion in solution. This reduction process leads to the deposition of such metal atoms onto the exposed n-type surface of the solar cell, simultaneously enhancing the plating process and preventing oxidation.

The application of the plated metal to the silicon surface has several benefits. Firstly, it makes good ohmic contact to both the exposed heavily doped silicon and also the screen-printed metal, overcoming the high contact resistance sometimes experienced when contacting screen-printed metals to silicon is attempted. Secondly, the increased conductivity of the plated semiconductor fingers facilitates increasing the screen-printed metal line spacing up to a range of 1-3 cm. However in one embodiment a spacing between the screen printed metal fingers of in the range of 3-6 mm has been found to work well. The corresponding width may be increased to typically 400 microns to accommodate increased current, but this has the benefit of allowing both tapering and increased height to 40-50 microns compared to normal screen-printed lines. This reduces the shading loss of the screen-printed metal fingers from typically 5% down to about 1%, with a corresponding Jsc increase. Interestingly the effective shading loss of the plated fingers was expected to be as calculated from their dimensions, but in reality, the plated laser doped surface appears rough enough to scatter the reflected light so that almost half is totally internally reflected at the glass/air interface of the encapsulation and returned to the solar cell surface. Therefore the effective shading loss of the plated fingers is only about half of what might be expected. Importantly, by using a screen-printed paste that does not penetrate through the dielectric layer, we avoid the contact between the screen-printed silver and the lightly doped silicon is avoided, providing a front surface design of this hybrid contact solar cell that behaves very differently to standard screen-printed contacts and appears to have the potential to achieve open circuit voltages approaching 700 mV.

### EXAMPLE 1

A typical processing sequence to form these hybrid contact devices is as follows:
1. Surface etching and texturing of the semiconductor substrate;
2. Front surface diffusion to form an emitter with sheet resistivity of at least 90 ohms/square
3. PhosphoSilicate Glass removal and rear surface etch for edge junction isolation;
4. PECVD deposition of top surface dielectric layer 43 such as silicon nitride or silicon oxynitride or silicon dioxide or aluminium oxide, etc;
5. Screen-print front and rear metal contacts 62, 63 at a spacing of 3 to 6 mm (grid on front)
6. Firing of screen-printed metal contacts at a temperature in the range of 750-850° C., simultaneously creating the rear field 16;
7. Coat the surface of the dielectric layer 43 with phosphoric acid 91 as a dopant source and pattern the surface with a laser 92, while simultaneously melting the silicon to allow it to be heavily doped with phosphorus, producing narrow parallel doped lines 65 of exposed silicon of width 3-30 microns and spaced 0.5 to 1.5 mm apart; in this process the laser is scanned perpendicular or at an angle crossing the silver fingers printed on the front whereby most doped lines cross silver fingers multiple times, preferably at or near perpendicular (i.e. generally perpendicular);
8. Removal of native oxide and other surface residues from the laser doped region 65 by HF etch or other means followed by subsequent rinsing while illuminating the wafer surface with a light source 104 of at least 1 mW/cm² light intensity (during both the oxide removal and washing steps);
9. Plating of metal 61 while illuminating the wafer surface with a light source 104 of at least 1 mW/cm² of light intensity. Examples of suitable metals for plating are silver or nickel or tin or nickel followed by silver or nickel followed by copper and silver or nickel followed by tin and silver or nickel followed by copper and tin and silver;
10. Sintering of the metal 61 at a temperature in the range 100° C. to 500° C.

### EXAMPLE 2

An alternative processing sequence to form these hybrid contact devices is as follows:
1. Surface etching and texturing of the semiconductor substrate;
2. Front surface diffusion to form an emitter 44 with sheet resistivity of at least 90 ohms/square
3. PhosphoSilicate Glass removal and rear surface etch for edge junction isolation;
4. PECVD deposition of surface dielectric layer 43 such as silicon nitride or silicon oxynitride or silicon dioxide or aluminium oxide, etc;
5. Coat the surface of the dielectric layer 43 with phosphoric acid 91 as a dopant source and pattern the surface with a laser 92, while simultaneously melting the silicon to allow it to be heavily doped with phosphorus, producing narrow parallel doped lines 65 of exposed silicon of width 3-30 microns and spaced 0.5 to 1.5 mm apart;
6. Screen-print front and rear metal contacts 62, 63 at a spacing of 3 to 6 mm whereby the silver fingers on the front are printed perpendicular or at an angle crossing the laser doped lines; whereby most silver fingers each cross multiple laser doped lines, preferably at or near perpendicular (i.e. generally perpendicular);
7. Firing of screen-printed metal contacts at a temperature in the range of 750-850° C., simultaneously creating the rear field 16;
8. Removal of native oxide and other surface residues from the laser doped region 65 by HF etch followed by subsequent rinsing while illuminating the wafer surface with a light source 104 of at least 1 mW/cm² light intensity (during both the oxide removal and washing steps);
9. Plating of metal 61 while illuminating the wafer surface with a light source 104 of at least 1 mW/cm² of light intensity. Examples of suitable metals for plating are silver or nickel or tin or nickel followed by silver or nickel followed by copper and silver or nickel followed by tin and silver or nickel followed by copper and tin and silver;
10. Sintering of the metal at a temperature not exceeding 500° C. (e.g. in the range 100° C. to 500° C.).

One variation of the above is to use inkjet technology or other approach to pattern the dielectric layer in step 7 of the first example (step 5 of the second example), following which the exposed silicon surface can be processed to prepare it for plating such as by thermally diffusing it with phosphorus or some other substance that will enhance plateability in those regions so that they will plate simultaneously with the screen-printed metal on the same wafer surface. This thermal diffusion process could be done in a furnace or rapid thermal annealer or by laser treatment.

A simplification to the above is to carry out steps 8 and 9 prior to screen-printing and firing in steps 5 and 6 of the first example (step 6 & 7 of the second example). Plated cells normally cannot withstand the firing conditions use for screen-printed contacts because: firstly they are normally at least 8 microns high and the thermal expansion mismatch between the metal and the silicon leads to them pealing off; and secondly, the metal penetration depth is at least several microns which penetrates through conventional p-n junctions for solar cells which are normally within about a microns of the surface.

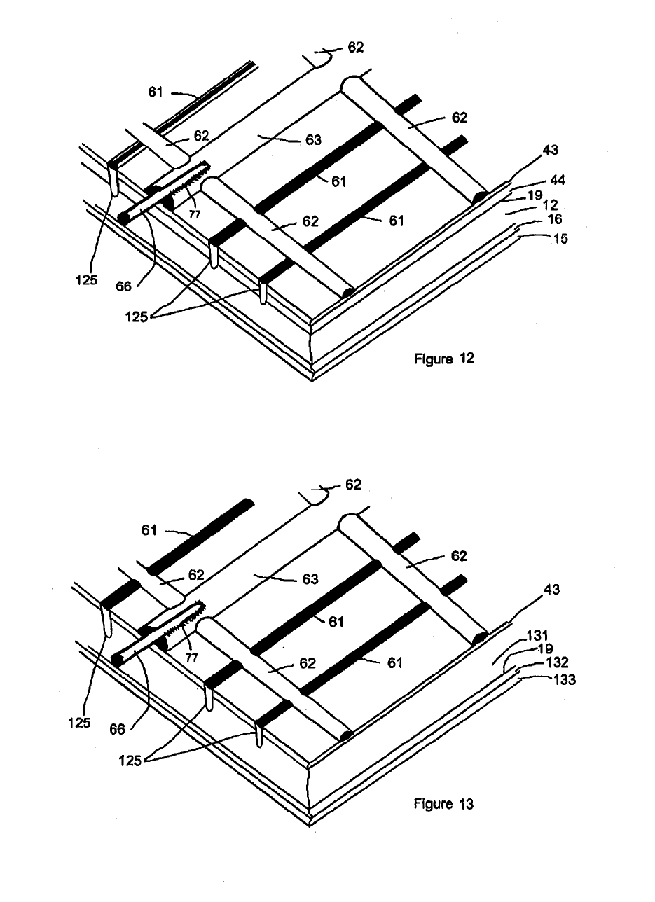

The first is solved by using a device design that only requires the metal to be plated to a thickness in the range 0.1 to 5 microns. The second is solved by using special laser doping in step 7 of the first example (step 5 of the second example), namely a use of a continuous wave laser 93 as seen in FIG. 11 that enables junction depths in excess of 5 microns to be formed without ablating significant amounts of the silicon.

Conventional Q-switched lasers emit pulses of energy typically every 10 microseconds. If the power of these pulses is correctly controlled, they can melt the silicon but avoid ablating it and therefore allow doping of the silicon to occur. However, the silicon will cool to close to ambient temperature while waiting typically 10 micro seconds for the next pulse. The process then repeats itself, but each pulse only melts approx the same volume (depth) of silicon, as the starting temperature is always close to ambient. Lasers of 532 nm wavelength are generally used for this purpose, limiting the melt depth to typically 1-2 microns. Using a higher power to get greater depth simply causes ablation of the silicon. A continuous wave (cw) laser 93 doesn't produce intermittent pulses but rather a continuous beam of energy which continues to heat the silicon, but far more gradually compared to the Q-switched laser. As heat is continuously added, the volume of molten silicon continues to grow and the depth increases to 5 or even 10 microns. A very high frequency Q-switched laser working at frequencies of from 500 khz to 70 MHz (compared to a more usual 100 kHz) can also be used to give a similar effect and gives a similar 3-5 microns or greater depth. When the pulse repetition frequency is so high, the molten silicon does not cool significantly between laser pulses and so the molten volume continues to grow, with the laser effectively behaving as a pseudo cw laser. A device made using a cw laser or Very High Frequency laser 93 is illustrated in FIG. 12 in which the heavily doped regions 125 are seen to extends through the remaining n-type front silicon layer 44.

Alternatively, a rear junction device structure as seen in FIG. 13 can be used although even in this case, the deep laser melted region 125 is preferable so that the metal penetration of the emitter caused by the firing of the screen printed contacts only takes place within heavily laser doped regions and therefore does not degrade the device voltage. In this case the wafer 131 is an n-type wafer and the rear silicon layer 132 is a p-type diffusion.

In the case where steps 8 and 9 are carried out prior to screen-printing and firing in steps 5 and 6 of the first example (step 6 & 7 of the second example), the second metal sintering step 10 is no longer required and neither is the wafer illumination during chemical processes to avoid oxidation of the surfaces being enhanced by the screen-printed silver.

A possible problem created by carrying out the plating first is that ghost plating may occur in unwanted areas where the dielectric layer does not properly protect the silicon surface. This can be minimised or even eliminated by reducing the surface doping concentration of the emitter in regions where plating is to be avoided. This can be done by optimising the emitter diffusion conditions such as by diffusing through a thin silicon dioxide layer so as to reduce the surface doping concentration, thereby making the surface lower conductivity and less attractive for plating. Alternatively, a heavier emitter diffusion than required can be effected in step 2 so that in step 3, an etch-back of the surface can be used to lower the surface concentration. It should be noted though that a particular strength of this hybrid technology is that by screen-printing the front surface metal prior to plating the patterned areas, the screen-printed metal protects all the silicon nitride coated regions from unwanted ghost plating. This overcomes a common problem experienced with plated cells.

It will be appreciated by persons skilled in the art that numerous variations and/or modifications may be made to the invention as shown in the specific embodiments without departing from the scope of the invention as broadly described. The present embodiments are, therefore, to be considered in all respects as illustrative and not restrictive.

1. A solar cell comprising:
a semiconductor body having a p-n junction located between a front (light receiving) semiconductor region and a back (non-light receiving) semiconductor region;
a dielectric layer extending over a front surface of the front semiconductor region;
one or more elongate semiconductor fingers formed on the front surface of the front semiconductor region, the semiconductor fingers being exposed through the dielectric layer, more heavily doped than the remainder of the front semiconductor region and of the same dopant polarity;
one or more elongate plated contacts formed to self align with and at least partially cover the semiconductor fingers;
one or more metal collection fingers extending over the dielectric layer, generally transversely to the plated contacts.

2. The solar cell of claim 1 wherein the one or more metal collection fingers extending generally transversely to the plated contacts are spaced at a minimum spacing of 3-6 mm.

3. The solar cell of claim 1 wherein the one or more metal collection fingers extending generally transversely to the plated contacts are formed as lines of fired metal paste.

4. The solar cell of claim 1 wherein the one or more metal collection fingers extending generally transversely to the plated contacts are plated contacts formed on a seeding material over the dielectric layer.

5. The solar cell of claim 1, wherein a busbar is provided, running generally transversely to the metal collection fingers.

6. The solar cell of claim 5 wherein the busbar is formed of a fired metal paste.

7. The solar cell of claim 5 wherein the busbar is a plated contact formed on a seeding material over the dielectric layer.

8. The solar cell as claimed in claim 1 wherein the metal collection fingers are tapered.

9. The solar cell of claim 5 wherein the metal collection fingers are tapered such that they are wider where they meet the busbar and become narrower as they extend from the busbar.

10. The solar cell of claim 1 wherein the fired metal paste collection fingers crossing the plated contacts are in the range of 40-60 microns high, or 10-80 microns or 10-20 microns or 20-30 microns or 30-40 microns or 40-50 microns or 50-60 microns or 60-70 microns or 70-80 microns high.

11. The solar cell of claim 1 wherein the fired metal paste collection fingers are 450-550 or 150-1000 microns or 150-200 microns or 200-300 microns or 300-500 microns or 400-500 microns or 500-600 microns or 600-700 microns or 700-800 microns or 800-900 microns or 900-1000 microns wide at one wider end and 50-1250 microns or 75-100 microns wide at another narrower end.

12. The solar cell of claim 1 wherein the plating height is in a range of 0.5-3 microns or 0.1-5.0 microns or 0.1-10 or 0.1-9.0 or 0.1-8.0 or 0.1-7.0 or 0.1-6.0 or 0.1-5.0 or 0.1-4.0 or 0.1-3.0 or 0.1-2.0 or 0.1-1.0 or 0.1-0.5 microns or 0.5-10 or 0.5-9.0 or 0.5-8.0 or 0.5-7.0 or 0.5-6.0 or 0.5-5.0 or 0.5-4.0 or 0.5-3.0 or 0.5-2.0 or 0.5-1.0 microns or 1.0-10 or 1.0-9.0 or 1.0-8.0 or 1.0-7.0 or 1.0-6.0 or 1.0-5.0 or 1.0-4.0 or 1.0-3.0 or 1.0-2.0 microns or 2.0-10 or 2.0-9.0 or 2.0-8.0 or 2.0-7.0 or 2.0-6.0 or 2.0-5.0 or 2.0-4.0 or 2.0-3.0 microns or 3.0-10 or 3.0-9.0 or 3.0-8.0 or 3.0-7.0 or 3.0-6.0 or 3.0-5.0 or 3.0-4.0 microns or 4.0-10 or 4.0-9.0 or 4.0-8.0 or 4.0-7.0 or 4.0-6.0 or 4.0-5.0 microns or 5.0-10 or 5.0-9.0 or 5.0-8.0 or 5.0-7.0 or 5.0-6.0 microns or 6.0-10 or 6.0-9.0 or 6.0-8.0 or 6.0-7.0 microns or 7.0-10 or 7.0-9.0 or 7.0-8.0 microns or 8.0-10.0 or 8.0-9.0 microns or 9.0-10.0 microns high.

13. The solar cell of claim 1 wherein the plated contacts have widths in the range of 10 to 30 microns or 5 to 50 or 5 to 40 or 5 to 30 or 5 to 20 or 5 to 10 microns or 10 to 50 or 10 to 40 or 10 to 30 or 10 to 20 microns or 20 to 50 or 20 to 40 or 20 to 30 microns or 30 to 50 or 30 to 40 microns or 40 to 50 microns.

14. The solar cell of claim 1 wherein the semiconductor fingers have a depth of at least 1 micron.

15. The solar cell of claim 1 wherein the semiconductor fingers have a depth of at least 5 microns.

16. The solar cell of claim 1 wherein the semiconductor fingers have a depth of at least 10 microns.

17. The solar cell of claim 1 wherein the p-n junction is a rear surface junction where the junction is formed adjacent the rear (non light receiving) surface of the semiconductor body and such that it is further from the front surface than it is from the rear surface of the solar cell.

18. The solar cell of claim 1 wherein the p-n junction is greater than 10 microns from a front semiconductor surface of the solar cell.

19.-56. (canceled)
